(19) United States
(12) Patent Application Publication
(10) Pub. No.: US 2007/0148867 A1
(43) Pub. Date: Jun. 28, 2007

(54) NONVOLATILE MEMORY DEVICES HAVING FLOATING GATES AND METHOD OF FABRICATING THE SAME

(76) Inventors: Chang-Mo Park, Seongnam-si (KR); Hong-Kook Min, Yonging-si (KR); Yong-Suk Choi, Hwaseong-si (KR)

Correspondence Address: Frank Chau, Esq.;F. CHAU & ASSOCIATES, LLC, 130 Woodbury Road, Woodbury, NY, 11797, US

(21) Appl. No.: 11/614,297

(22) Filed: Dec. 21, 2006

(30) Foreign Application Priority Data
Dec. 23, 2005 (KR) 2005-128635

(51) Int. Cl. H01L 21/336

(52) U.S. Cl. 438/257; 438/261; 438/264

(57) ABSTRACT

A nonvolatile memory device includes a liner covering a sidewall and bottom of a trench that defines an active field in a substrate and a field isolation film disposed on the liner which fills the trench. The nonvolatile memory device further includes a floating gate disposed on the active field having an edge of which covers the liner, a tunnel insulation film interposed between the active field and the floating gate and a charge diffusion barrier interposed between the liner and the floating gate.

### CROSS-REFERENCE TO RELATED APPLICATIONS

This U.S. non-provisional patent application claims priority under 35 U.S.C. § 119 of Korean Patent Application 2005-128635 filed on Dec. 23, 2005, the contents of which are hereby incorporated by reference herein in their entirety.

### BACKGROUND

1. Technical Field

The subject matter described herein is concerned with semiconductor devices and methods of fabricating the same, and in particular relates to nonvolatile memory devices with floating gates and methods of fabricating the same.

2. Description of the Related Art

Nonvolatile memory devices are operable and retain their stored data, even without an external power supply. For example, a typical kind of the nonvolatile memory device is a flash memory device. A Flash memory device may employ an electrically isolated floating gate as an element for storing data. In addition, according to the presence of charges in the floating gate, a data bit may be differentiated into logic ‘0’ or ‘1’ by a unit cell of the flash memory device.

Moreover, unit cells of the flash memory device are formed in active fields defined by field isolation films. Also, with the tendency towards higher integration density in semiconductor devices, recent flash memory devices usually include trench-type field isolation films with high insulation characteristics.

FIGS. 1 and 2 are sectional views showing a procedure of fabricating a general flash memory device.

Referring to FIG. 1, on a semiconductor substrate 1, a buffering oxide film 2 and a hard mask pattern 3 are deposited in sequence. Using the hard mask pattern 3 for a mask, the semiconductor substrate 1 is selectively etched to form trenches 4 that define active fields therein.

Then, sidewall oxide films 5 are formed on bottoms and sidewalls of the trenches 4. The sidewalls 5 are formed of thermal oxide for curing etching damages on the bottoms and sidewalls of the trenches 4.

Thereafter, a silicon nitride film 6 is formed all over the semiconductor substrate 1. Next, an oxide film 7 is deposited on the silicon nitride film 6, filling the trenches 4.

Referring to FIG. 2, the oxide film 7 and the silicon nitride film 6 are flattened until exposing the hard mask pattern 3, thereby resulting in liners 6a and field isolation films 7a being sequentially stacked in the trenches 4. The exposed hard mask pattern 3 is removed to expose the buffering oxide film 2 and the exposed buffering oxide film 2 is removed to expose surfaces of the active fields.

The field isolation films 7a could stress the trenches 4 to cause various defects thereon and thus the liners 6a function to lessen such possible stress from the field isolation films 7a.

Subsequently, tunnel oxide films 8 are deposited each on the exposed upward faces of the active fields. The tunnel oxide films 8 are made of thermal oxide. Floating gates 9 are stacked each on the tunnel oxide films 8. Channel regions are confined in the active fields under the floating gates 9. Both edges of the floating gate 9 cover and contact the tops of the liners 6a. Further, the floating gates 9 are able to cover edges of the field isolation films 7a. Although not shown, a control gate electrode covers the floating gate 9, and an insulation film is interposed between the control gate electrode and the floating gate 9.

According to the aforementioned procedure for fabricating a flash memory device, the silicon nitride film used as the liners 6a has traps with deep potential. The tops of such liners 6a contact to the floating gate 9 and thus charges (e.g., holes) of the floating gate 9 may be diffused into the liners 6a through the contacting interfaces thereof. The charges put into the liners 6a can be stored in the traps therein. With this mechanism, the channel region adjacent to the liners 6a may be partially applied with electric fields by the trapped charges. As a result, even when a turn-off voltage is induced at the floating gate 9 to turn the channel region off, the trapped charges (e.g., holes) of the liners 6a may render the channel region, which is adjacent to the liners 6a, conductive. Consequently, a leakage current through the channel region adjacent to the liners 6a may occur.

Moreover, especially during a bake testing operation for confirming the reliability of flash memory device, the diffusion of the charges into the liners 6a from the floating gate 9 may be deepened and may significantly degrade the reliability of flash memory device.

### SUMMARY OF THE INVENTION

The exemplary embodiments of the present invention provide nonvolatile memory devices which prevent charges from diffusing into liners out of a floating gate, and methods of fabricating the same.

In accordance with an exemplary embodiment of the present invention, a nonvolatile memory device is provided. The nonvolatile memory device includes a liner covering sidewall and bottom of a trench that defines an active field in a substrate and a field isolation film disposed on the liner which fills the trench. The nonvolatile memory device further includes a floating gate disposed on the active field having an edge of which covers the liner, a tunnel insulation film interposed between the active field and the floating gate and a charge diffusion barrier interposed between the liner and the floating gate.

According to an exemplary embodiment, the tunnel insulation film may comprise first and second insulation layers. Here, the second insulation layer extends laterally to be interposed between the floating gate and the liner. The second insulation layer interposed between the floating gate and the liner is the charge diffusion barrier. The first insulation layer may be a thermal oxide film while the second insulation film may be an oxide film formed by means of chemical vapor deposition or atomic layer deposition.

According to an exemplary embodiment, the charge diffusion barrier may be interposed between the field isolation and an upper portion of the sidewall of the trench. Here, the charge diffusion barrier may be stacked on the liner interposed between the field isolation film and the sidewall of the trench. In this case, the charge diffusion barrier is an oxide film oxidized by radical oxygen.

According to an exemplary embodiment, the nonvolatile memory device may further comprise a control gate electrode crossing over the active field, being coupled to the floating gate.

According to an exemplary embodiment, the nonvolatile memory device may further comprise: a capping oxide pattern disposed on the floating gate, having an elliptical section and a control gate insulation film interposed at least between the control gate electrode and a sidewall of the floating gate and between the active field and the control gate electrode. In this case, the control gate electrode may cover the sidewall of the floating gate and partially the top of the floating gate, and a part of the active field adjacent to the sidewall of the floating gate. Here, a top edge of the floating gate is shaped in a sharpened tip and the capping oxide pattern is partially disposed between the floating gate and the control gate electrode.

According to an exemplary embodiment, the nonvolatile memory device may further comprise an interlevel gate dielectric pattern interposed between the floating gate and the control gate electrode. In this case, the control gate electrode may entirely cover the floating gate and have a couple of sidewalls aligned to both sidewalls of the floating gate.

According to an exemplary embodiment, the nonvolatile memory device may further comprise a sidewall oxide film interposed between the liner and the sidewall of the trench and between the liner and a bottom of the trench.

In accordance with an exemplary embodiment of the present invention a method for fabricating a nonvolatile memory device is provided. The method includes forming a trench to define an active field in a substrate, forming a liner to cover a sidewall and bottom of the trench, forming a field isolation film on the liner to fill the trench, forming a tunnel insulation film on the active field, forming a floating gate, over the active field, wherein the floating gate has an edge which covers the liner and forming a charge diffusion barrier interposed between the liner and the floating gate.

According to an exemplary embodiment, forming the tunnel insulation film and the charge diffusion barrier may be comprised of thermally oxidizing the substrate to form a thermal oxide film on the surface of the active field and depositing an oxide film on the substrate by means of chemical vapor deposition or atomic layer deposition. In this case, the floating gate is formed on the deposited oxide film, the thermal and deposited oxide films interposed between the floating gate and the active field are correspondent with the tunnel insulation film, and the deposited oxide film interposed between the floating gate and the liner is the charge diffusion barrier.

According to an exemplary embodiment, forming the charge diffusion barrier may be comprised of conducting radical oxidation on the substrate with radical oxygen and oxidizing the top of the liner. Here, the oxidized top of the liner is the charge diffusion barrier. In this case, the tunnel insulation film may be formed by oxidizing the surface of the active field by the radical oxidation. On the other hand, forming the tunnel insulation film may be comprised of thermally oxidizing the surface of the active field before the radical oxidation.

According to an exemplary embodiment, the method may further comprise forming a control gate electrode to cross over the active field and to be coupled to the floating gate.

### BRIEF DESCRIPTION OF THE FIGURES

Exemplary embodiments of the present invention can be understood in more detail from the following description taken in conjunction with the accompanying drawings, in which:

FIGS. 1 and 2 are sectional views showing a procedure of fabricating a general flash memory device;

FIG. 3 is a sectional view illustrating a nonvolatile memory device in accordance with an exemplary embodiment of the invention;

FIG. 4 is a sectional view taken along line I-I′ of FIG. 3;

FIGS. 5A through 9A are sectional views illustrating a procedure of fabricating the nonvolatile memory device shown in FIG. 3;

FIGS. 5B through 9B are sectional views taken along line II-II′ of FIGS. 5A through 9A;

FIG. 10 is a sectional view illustrating a nonvolatile memory device in accordance with an exemplary embodiment of the invention;

FIG. 11 is a sectional view taken along line III-III′ of FIG. 10;

FIGS. 12A and 13A are sectional views illustrating a procedure of fabricating the nonvolatile memory device shown in FIG. 10;

FIGS. 12B and 13B are sectional views taken along line IV-IV′ of FIGS. 12A and 13A;

FIG. 14 is a sectional view illustrating a nonvolatile memory device in accordance with an exemplary embodiment of the invention;

FIG. 15 is a sectional view taken along line V-V′ of FIG. 14;

FIGS. 16A and 17A are sectional views illustrating a procedure of fabricating the nonvolatile memory device shown in FIG. 14;

FIGS. 16B and 17B are sectional views taken along line VI-VI′ of FIGS. 16A and 17A;

FIG. 18 is a sectional view illustrating a nonvolatile memory device in accordance with an exemplary embodiment of the invention;

FIG. 19 is a sectional view taken along line VII-VII′ of FIG. 18;

FIGS. 20A and 21A are sectional views illustrating a procedure of fabricating the nonvolatile memory device shown in FIG. 18; and

FIGS. 20B and 21B are sectional views taken along line VIII-VIII′ of FIGS. 20A and 21A.

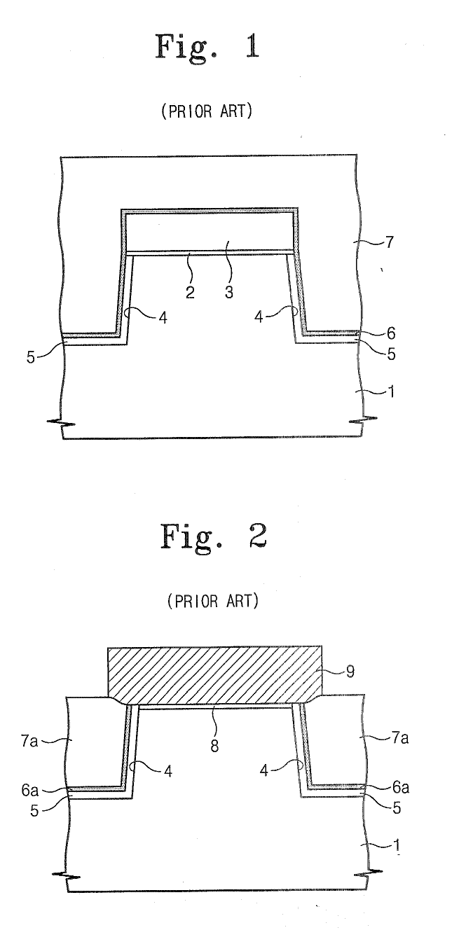

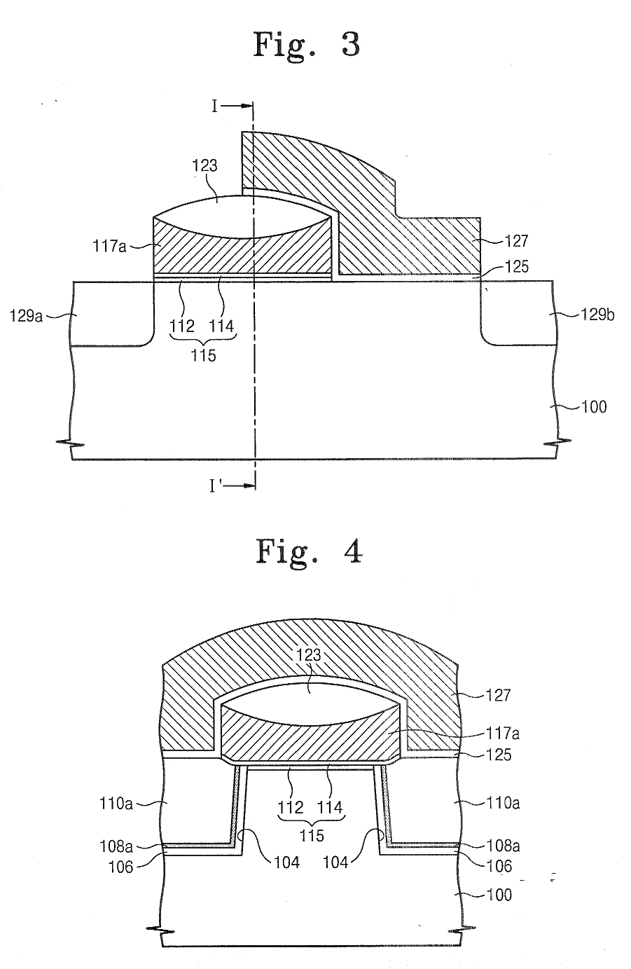

### DETAILED DESCRIPTION OF THE EXEMPLARY EMBODIMENTS

Exemplary embodiments of the present invention will be described below in more detail with reference to the accompanying drawings. The present invention may, however, be embodied in different forms and should not be constructed as limited to the exemplary embodiments set forth herein.

In the figures, the dimensions of layers and regions are exaggerated for clarity of illustration. It will also be understood that when a layer (or film) is referred to as being ‘on’ another layer or substrate, it can be directly on the other layer or substrate, or intervening layers may also be present. Further, it will be understood that when a layer is referred to as being ‘under’ another layer, it can be directly under, and one or more intervening layers may also be present. In addition, it will also be understood that when a layer is referred to as being ‘between’ two layers, it can be the only layer between the two layers, or one or more intervening layers may also be present. Like reference numerals refer to like elements throughout.

### FIRST EXEMPLARY EMBODIMENT

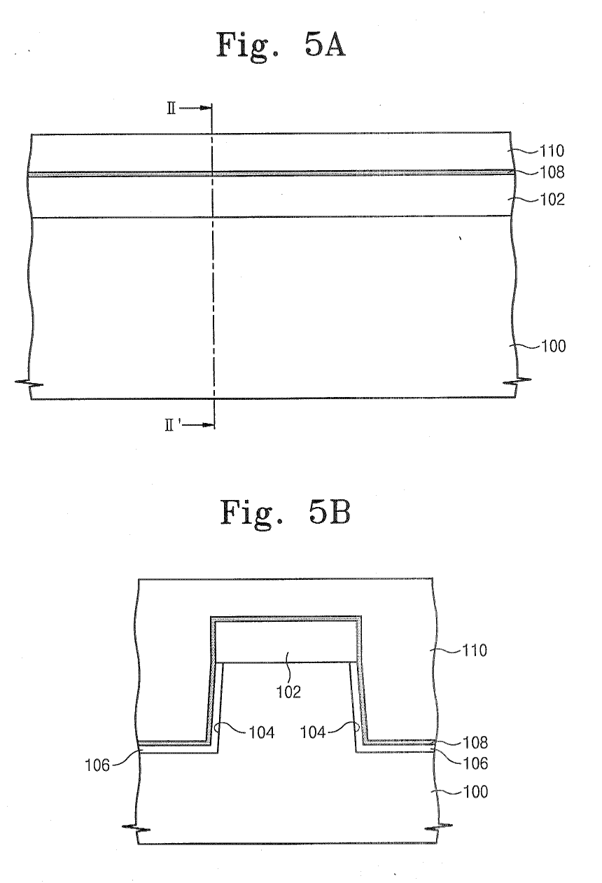

FIG. 3 is a sectional view illustrating a nonvolatile memory device in accordance with an exemplary embodiment of the invention, and FIG. 4 is a sectional view taken along line I-I′ of FIG. 3

Referring to FIGS. 3 and 4, trenches 104 are placed in a semiconductor substrate (hereinafter, referred to as ‘substrate’) 100, defining active fields. The bottoms of the trenches 104 are leveled lower than the top of the substrate 100. Liners 108a are formed covering bottoms and sidewalls of the trenches 104. Field isolation films 110a are disposed on the liners 108a, filling the trenches 104. Each of the liners 108a is interposed among the field isolation film 110a and the sidewall and bottom of the trench 104. Sidewall oxide films 106 are formed on the bottoms and sidewalls of the trenches 104. Each of the sidewall oxide films 106 is interposed among the field isolation film 110a and the sidewall and bottom of the trench 104. The field isolation films 110a may be made of, for example, oxide by means of chemical vapor deposition (CVD). The sidewall oxide films 106 may be formed of, for example, thermal oxide. The liners 108a may be made of, for example, nitride capable of buffing physical stress from the field isolation films 110a.

Over the active field is disposed a floating gate 117a. Here, edges of the floating gate 117a cover the tops of the liners 108a and are disposed between the field isolation films 110a and the sidewalls of the trenches 104. The edges of the floating gate 117a may laterally extend to overlap with edges of the field isolation films 110a adjacent to the active fields.

Between the floating gate 117a and the active field is interposed a tunnel insulation film 115. The tunnel insulation film 115 includes first and second insulation layers 112 and 114 which are stacked in sequence. The second insulation layer 114 of the tunnel insulation film 115 laterally extends to be interposed between the floating gate 117a and the liners 108a. The second insulation layer 114, which is placed between the floating gate 117a and the liners 108a, functions as a charge diffusion barrier. This charge diffusion barrier is made of an insulative material capable of preventing charges from diffusing. For instance, the charge diffusion barrier is preferred to be formed of, for example, oxide. The charge diffusion barrier prevents charges from penetrating into the liners 108a out of the floating gate 117a.

For example, the first and second insulation layers 112 and 114 to be formed, respectively, of thermal oxide and oxide that may be deposited by means of CVD or atomic layer deposition (ALD). Thus, it is possible to prevent the degradation of the reliability of the device through the tunnel insulation film 115. In detail, as the first insulation film 112 of thermal oxide contacts the surface of the active field, it is able to prevent degradation of interface characteristic between the tunnel insulation film 115 and the active field. If an oxide deposited thereon contacts the active field, it may result in an increase in interface defects, such as dangling bonds, at the interface between the tunnel insulation film and the active field. However, as aforementioned, as the first insulation layer 112, which substantially contacts the active field, as a part of the tunnel insulation film 115, is formed of thermal oxide, it is possible to prevent the degradation of interface characteristics between the tunnel insulation film 115 and the active field. Further, as the second insulation layer 114 is used in forming the top of the tunnel insulation film 115 and the charge diffusion barrier, it prevents charges from diffusing into the liners 108a out of the floating gate 117a.

A capping oxide pattern 123 is disposed on the floating gate 117a. The capping oxide pattern 123 has a section configured in, for example, an elliptical shape, being flattened on the top and bottom thereof. Accordingly, the top edges of the floating gate 117a become sharpened in the shape of tips. A control gate electrode 127 crosses over the active field, being capacitively coupled with the floating gate 117a.

The control gate electrode 127 covers a partial top of the floating gate 117a, and a sidewall of the floating gate 117a that is adjacent to the partial top thereof. In other words, the control gate electrode 127 partially covers the tip-shaped top edge of the floating gate 117a. In addition thereto, the control gate electrode 127 partially covers the active fields around a sidewall of the floating gate 117a. The capping oxide pattern 123 is partially interposed between the control gate electrode 127 and the partial top of the floating gate 117a. A control gate insulation film 125 is at least placed between the control gate electrode 127 and the sidewall of the floating gate 117a, and between the control gate electrode 127 and the active field. The control gate insulation film 125 may extend to be interposed even between the capping oxide pattern 123 and the control gate electrode 127.

A first impurity region 129a is disposed in the active field at a side of the floating gate 117a, while a second impurity region 129b is disposed in the active field at a side of the control gate electrode 127. The first and second impurity regions 129a and 129b are isolated from each other. Namely, the floating gate 117a and the control gate electrode 127 are placed over the active field between the first and second impurity regions 129a and 129b. A channel region confined between the first and second impurity regions 129a and 129b is comprised of a first channel set under the floating gate 117a and a second channel set under a portion of the control gate electrode 127 that partially covers the active field.

According to the nonvolatile memory device of the present exemplary embodiment with the aforementioned structure, between the floating gate 117a and the liners 108a is interposed the charge diffusion barrier that is an extending portion from the second insulation layer 114 of the tunnel insulation film 115. Thus, the device of the present exemplary embodiment prevents charges from diffusing into the liners 108a out of the floating gate 117a, and interrupting leakage current through a channel region adjacent to the liners.

Furthermore, the tunnel insulation film 115 contacts the active field through the first insulation layer 112 that is made of thermal oxide having improved interface characteristics. Therefore, the device of the present exemplary embodiments prevents the flow of leakage current by means of the charge diffusion barrier with the extending portion of the second insulation layer 114, thereby providing operational reliability for the nonvolatile memory device.

FIGS. 5A through 9A are sectional views illustrating a procedure of fabricating the nonvolatile memory device shown in FIG. 3, and FIGS. 5B through 9B are sectional views taken along line II-II′ of FIGS. 5A through 9A.

First, referring to FIGS. 5A and 5B, a hard mask pattern 102 is formed on a predetermined area of the substrate 100. The hard mask pattern 102 contains a material having etching selectivity to the substrate 100. For example, the hard mask pattern 102 may be composed of oxide and nitride films stacked thereon in sequence.

Using the hard mask pattern 102 for a mask; the substrate 100 is selectively etched to form trenches 104 defining the active fields. In addition, the sidewall oxide films 106 are deposited on the sidewalls and bottoms of the trenches 104. The sidewall oxide films 106 are preferred to be made of thermal oxide. The sidewall oxide films 106 contribute to cure etching damages on the sidewalls and bottoms of the trenches 104.

Next, a liner film 108 is deposited all over the substrate 100. The liner film 108 covers the sidewall oxide films 106. The liner film 108 may be formed of nitride. Moreover, an insulation film 110 is deposited on the liner film 108 to fill the trenches 104. The insulation film 110 may be formed of, for example, an oxide by means of CVD. For example, the insulation film 110 may be formed of oxide by means of CVD using high-density plasma.

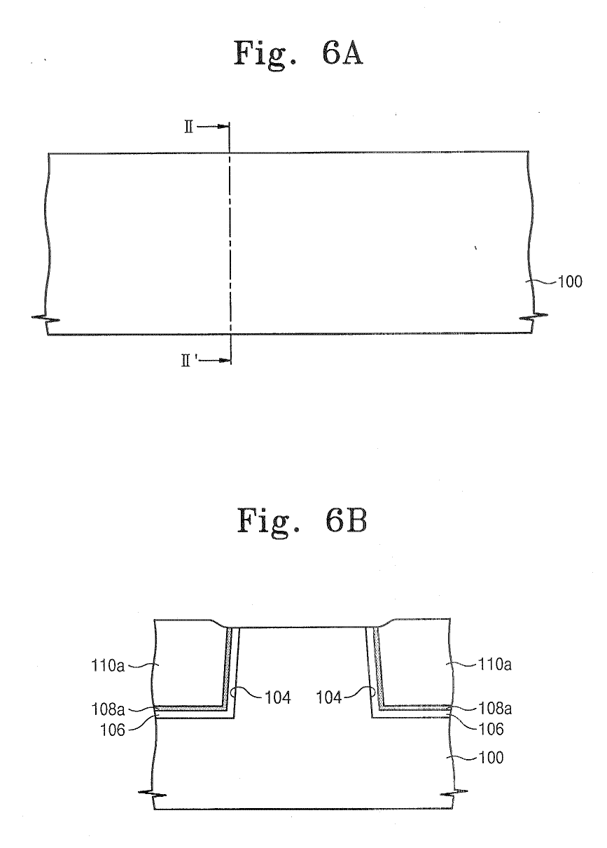

Next, referring to FIGS. 6A and 6B, the insulation film 110 is flattened (or planarized) until exposing the liner film 108 on the hard mask pattern 102 or exposing the hard mask pattern 102, resulting in the field isolation films 110a therein. The planarization process may be carried out with a chemical-mechanical polishing (CMP) operation. The liner film 108 and an upper portion of the hard mask pattern 102 may be formed of the same material, e.g., nitride. During the planarization, the liner film 108 or the hard mask pattern 102 can be exposed thereby.

The exposed hard mask pattern 102 is removed to expose the surface of the active field. The hard mask pattern 102 can be removed by way of a wet etching operation. While removing the hard mask pattern 102, the liner film 108 on sidewalls of the hard mask pattern 102 is also removed therefrom, thereby resulting in the liners 108a being disposed between the sidewall oxide films 106 and the field isolation films 110a. The tops of the liners 108a are exposed. In the case that the hard mask pattern 102 is composed of oxide and nitride films stacked in sequence, the field isolation films 110a may be partially etched away while removing the oxide film of the hard mask pattern 102 therefrom.

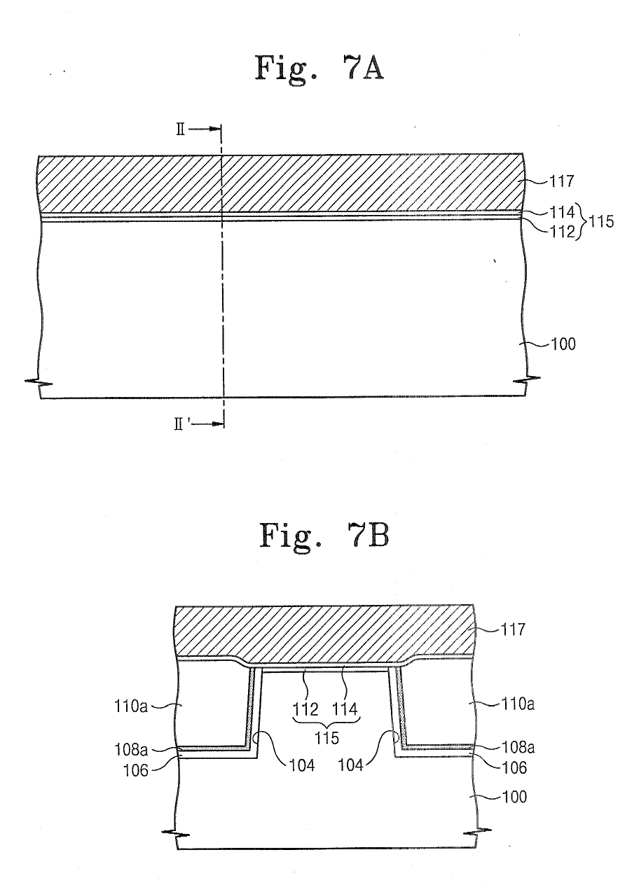

Then, referring to FIGS. 7A and 7B, the substrate 100 including the disclosed active fields is thermally oxidized to form the first insulation layer 112. As the first insulation layer 112 is made of thermal oxide, it is able to be formed on the exposed surface of the active field.

Thereafter, the second insulation layer 114 is deposited all over the substrate 100 including the first insulation layer 112, by means of, for example, chemical vapor deposition (CVD) or atomic layer deposition (ALD). The second insulation layer 114 is used for an insulation film to block the diffusion of charges. For instance, the second insulation layer 114 is preferred to be made of oxide. The second insulation layer 114 covers the first insulation layer 112. The second insulation layer 114 also covers the field isolation films 110a and the tops of the liners 108a. The first and second insulation layers 112 and 114 constitute the tunnel insulation film 115.

After forming the second insulation layer 114, thermal treatment is carried out to enhance the interface characteristic between the first and second insulation layers 112 and 114.

Then, a floating gate film 117 is deposited all over the substrate 100 including the second insulation layer 114. For example, floating gate film 117 is preferred to be formed of a semiconductor, such as doped polysilicon.

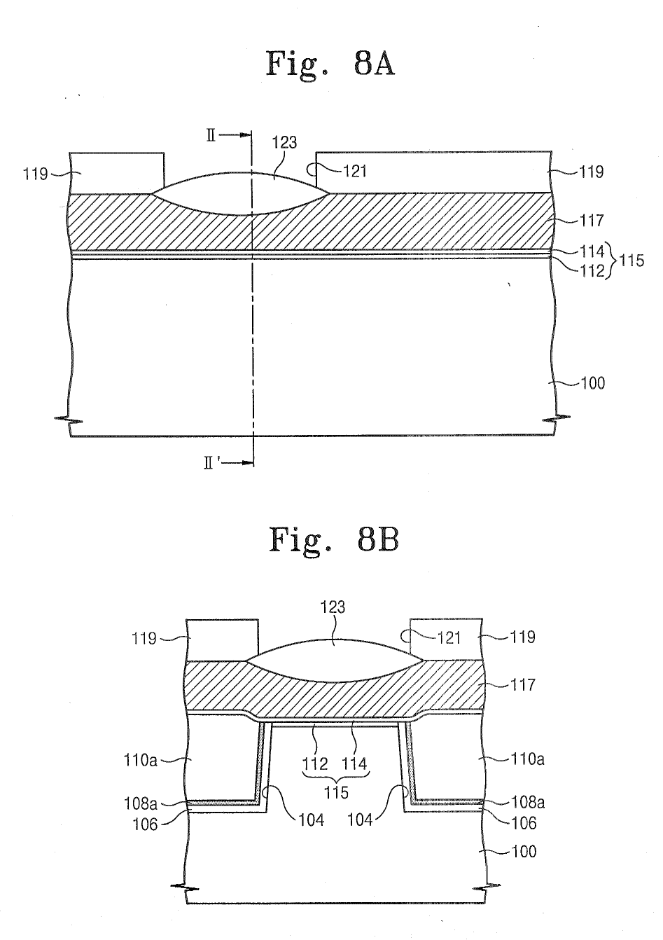

Subsequently, referring to FIGS. 8A and 8B, an oxidation protecting film 119 is deposited on the floating gate film 117. The oxidation protecting film 119 may be comprised of, for example, a nitride film. The oxidation protecting film 119 is patterned to form an opening 121 that exposes a predetermined region of the floating gate film 117.

The substrate 100 is thermally oxidized to the capping oxide pattern 123 on the floating gate film 117 that is partially being exposed through the opening 121. The capping oxide pattern 123 may be configured such that the center is thicker than the edges because there is a gap of oxygen tension rates between the central and sidewall regions in the opening 121. Namely, the capping oxide pattern 123 is formed having an elliptical section. The edge of the capping oxide pattern 123 may be placed under the oxidation protecting film 119 that constructs sidewalls of the opening 121.

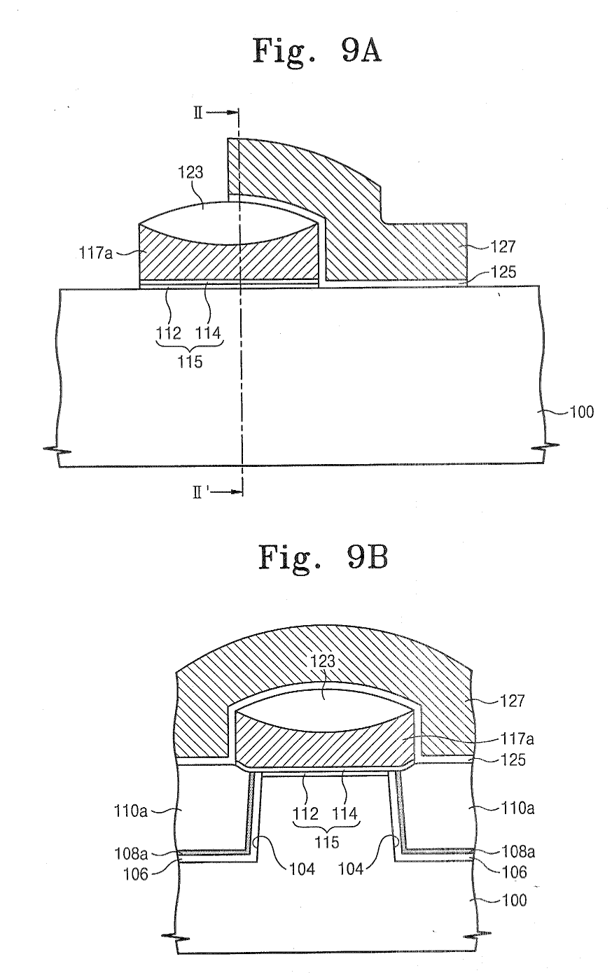

Next, referring to FIGS. 9A and 9B, the oxidation protection film 119 is removed to expose the top of the floating gate film 117. Next, using the capping oxide pattern 123 as a mask, the floating gate film 117 is patterned to the floating gates 117a . The top edges of the floating gates 117a are configured in sharpened tips along the elliptical profile of the capping oxide pattern 123.

The control gate insulation film 125 and a control gate conductive film are then sequentially deposited all over the substrate 100. The control gate conductive film is patterned to the control gate electrode 127 that crosses over the active field and is capacitively coupled to the floating gate 117a. The control gate insulation film 125 around the control gate electrode 127 may be removed by way of a wet etching operation. The control gate electrode 127 covers a part of the capping oxide pattern 123, a sidewall of the floating gate 117a, and a part of the active field adjacent to the sidewall of the floating gate 117a. The control gate insulation film 125 may be formed of, for example, thermal oxide. Alternatively, the control gate insulation film 125 may include an insulation film deposited by CVD or ALD. The control gate electrode 127 may be made of one material from, for example, doped polysilicon, metal (e.g., tungsten or molybdenum), conductive metal nitride (e.g., titanium nitride or tantalum nitride), and metal silicide (tungsten silicide or cobalt silicide).

Next, using a mask with the control gate electrode 127 and the floating gate 117a, ionic impurities are implanted into the substrate 100 to form the first and second impurity regions 129a and 129b, thereby resulting in the production of the nonvolatile memory device shown in FIGS. 3 and 4.

### SECOND EXEMPLARY EMBODIMENT

This exemplary embodiment shows various types of the charge diffusion barrier. The nonvolatile memory device according to this exemplary embodiment is similar to that of the first embodiment. It is noted that elements in the present exemplary embodiment which are the same as elements in the first exemplary embodiment will be referred to using the same reference numerals used in the first exemplary embodiment.

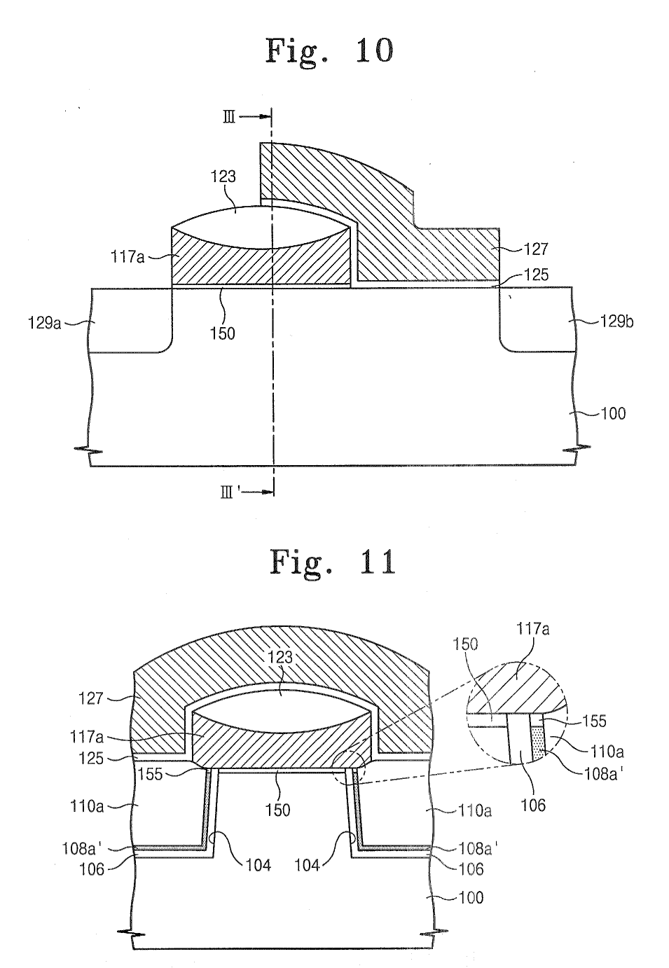

FIG. 10 is a sectional view illustrating a nonvolatile memory device in accordance with a second exemplary embodiment of the invention, and FIG. 11 is a sectional view taken along line III-III′ of FIG. 10.

Referring to FIGS. 10 and 11, the trenches 104 are formed in the substrate 100, defining the active fields therein. Liners 108a′ cover the bottoms and sidewalls of the trenches 104. The field isolation films 110a are disposed on the liners 108a′, filling the trenches 104. A charge diffusion barrier 155 is disposed on the liners 108a′ interposed between the field isolation films 110a and sidewalls of the trenches 104. The charge diffusion barriers 155 are disposed between the field isolation films 110a and upper portions of the sidewalls of the trenches 104. The charge diffusion barriers 108a′contact the tops of the liners 108a′ interposed between the field isolation films 110a and the sidewalls of the trenches 104.

The sidewall oxide films 106 are formed on the sidewalls and bottoms of the trenches 104. Here, the sidewall oxide films 106 are interposed between the liners 108a′ and the sidewalls and bottoms of the trenches 104. Further, the sidewall oxide films 106 are partially interposed between the charge diffusion barriers 155 and the upper portions of the sidewalls of the trenches 104. For example, the tops of the liners 108a′ is preferred to be leveled lower than the tops of the sidewall oxide films 106 formed on the sidewalls of the trenches 104.

The floating gates 117a are disposed over the active fields. The edges of the floating gates 117a cover the charge diffusion barriers 155. In other words, the charge diffusion barriers 155 are located between the edges of the floating gates 110a and the tops of the liners 108a′. Additionally, as aforementioned with regard to the first exemplary embodiment, the edges of the floating gates 117a may overlap with the edges of the field isolation films 110a adjacent to the active fields.

The charge diffusion barriers 155 are made of an insulation material to prevent charges from diffusing out of the floating gates 117a. For instance, the charge diffusion barriers 155 are preferred to be formed of oxide. For example, it is preferred for the charge diffusion barriers 155 to be made of an oxide film generated by oxidation with radical oxygen (hereinafter, referred to as ‘radical oxide film’). In further detail, the charge diffusion barriers 155 are preferred, for example, to be composed of such radical oxide films that are generated from oxidizing the tops of the liners 108a shown in FIG. 3.

The charge diffusion barriers 155 contribute to preventing charges from penetrating into the liners 108a′ out of the floating gate 117a thereby, blocking leakage current and lessening degradation of reliability of the nonvolatile memory device.

A tunnel insulation film 150 is placed between the floating gate 117a and the active field. The tunnel insulation film 150 may be composed of, for example, a radical oxide film generated from oxidizing the active field with radical oxygen. Alternatively, the tunnel insulation film 150 may be made of thermal oxide. The tunnel insulation film may be formed containing, for example, thermal and radical oxides. In other words, the tunnel insulation film 150 contacts the active field through a thermal or radical oxide film, thereby providing higher interface characteristics between the tunnel insulation film and the active field, without degradation thereof.

As other descriptions for the structural features of the capping oxide pattern 123 on the floating gate 117a, the control gate insulation film 125, the control gate electrode 127, and the first and second impurity regions 129a and 129b are the same as for the first exemplary embodiment, these features will not be discussed in further detail in the present exemplary embodiment.

Now the processing features of fabricating the nonvolatile memory device according to the present exemplary embodiment will be explained. These processing steps may include those illustrated in FIGS. 5A, 5B, 6A, and 6B.

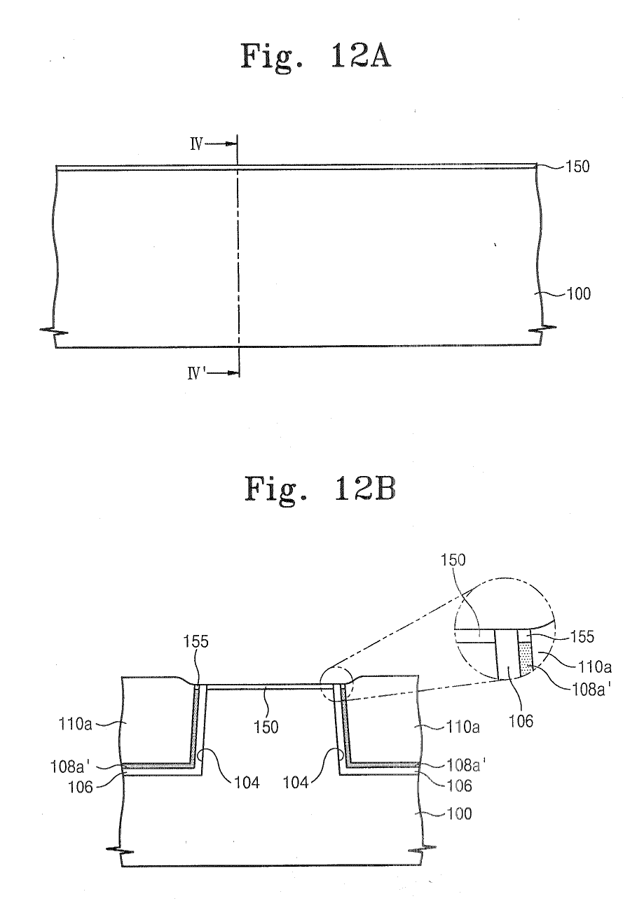

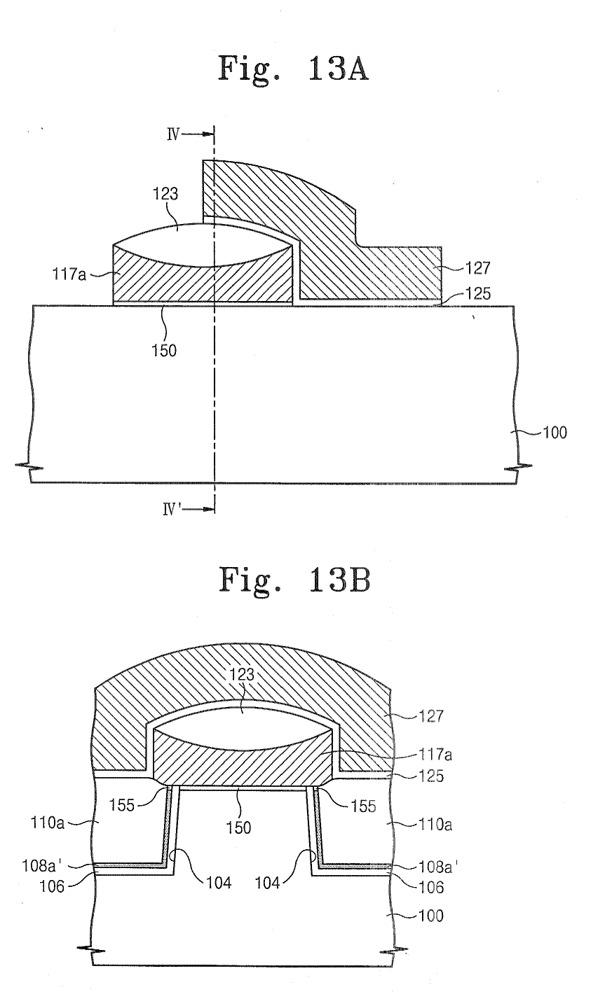

FIGS. 12A and 13A are sectional views illustrating a procedure of fabricating the nonvolatile device shown in FIG. 10, and FIGS. 12B and 13B are sectional views taken along line IV-IV′ of FIGS. 12A and 13A.

First, referring to FIGS. 6A, 6B, 12A, and 12B, the operation of oxidation with radical oxygen is carried out on the substrate 100 where the tops of the liners 108a are exposed, thereby radically oxidizing the tops of the liners 108a to generate the charge diffusion barriers 155. The tops of the liners 108a′ under the charge diffusion barriers 155 may be leveled lower than the tops of the sidewall oxide films 106 formed on the sidewalls of the trenches 104.

This radical oxidation is a process carried out in the procedure of first generating radical oxygen out of the reaction chamber in progress of oxidation and then injecting the radical oxygen into the reaction chamber to oxidize the substrate 100. For instance, after conditioning source gas, e.g., oxygen (O₂) or ozone (O₃), into plasma out of the reaction chamber, the radical oxygen among the plasma oxygen source gases is injected into the reaction chamber in the manner of diffusion. Such radical oxygen atoms are strongly reactive with semiconductor atoms (e.g., silicon atoms) of the liners 108a even made of nitride. As a result, the radical oxidation makes the tops of the liners 108a sufficiently oxidized to generate the charge diffusion barriers 155.

Next, the tunnel insulation film 150 is deposited on the active field. The tunnel insulation film 150 may be formed of, for example, a radical oxide made by way of the radical oxidation process that oxidizes the active field. For example, the radical oxidation may be carried out to form the tunnel insulation film 150 on the active field, and the charge diffusion barriers 155 on the liners 108a′, one at a time.

Alternatively, the tunnel insulation film 150 may be formed by means of thermal oxidation before beginning the radical oxidation. In further detail, the tunnel insulation film 150 can be made of, for example, thermal oxide. In this case, the radical oxidation is conducted after completing the thermal oxidation. Therefore, the tunnel insulation film 150 may be constructed in the structure with a thin radical oxide film on a thermal oxide film. Namely, the tunnel insulation film 150 may be comprised of, for example, the thermal and radical oxide films.

Next, referring to FIGS. 13A and 13B, on the substrate 100 including the tunnel insulation film 150 and the charge diffusion barriers 155, the floating gate 117a and the capping oxide pattern 123 are stacked in sequence. The floating gate 117a is placed over the active field through the tunnel insulation film 150. The edges of the floating gate 117a cover the charge diffusion barriers 155. The floating gate 117a and the capping oxide pattern 123 may be formed the same way as in the first exemplary embodiment. Namely, after depositing the floating gate film all over the substrate 100 including the tunnel insulation film 150 and the charge diffusion barriers 155, the capping oxide film 123 is formed by partially oxidizing the floating gate film using the oxidation protecting film. Then the floating gate 117a is formed by patterning the floating gate film using the capping oxide pattern 123 as a mask.

Subsequently, the procedure continues to form the control gate electrode 127 crossing over the active field, and the control gate insulation film 125 interposed between the control gate electrode 127 and a sidewall of the floating gate 117a and between the control gate electrode 127 and the active field. In this exemplary embodiment, the forming of the control gate insulation film 125 and the control gate electrode 127 are the same as for the first exemplary embodiment.

Next, using a mask with the control gate electrode 127 and the floating gate 117a, ionic impurities are injected into the active fields to form the first and second impurity regions 129a and 129b shown in FIG. 10, thereby producing the nonvolatile memory device shown in FIGS. 10 and 11.

### THIRD EXEMPLARY EMBODIMENT

This exemplary embodiment provides a nonvolatile memory device with a stacked structure of a floating gate and a control gate electrode. The structure according to this embodiment is applicable to a NAND (not and) or (not or) NOR-type nonvolatile memory device.

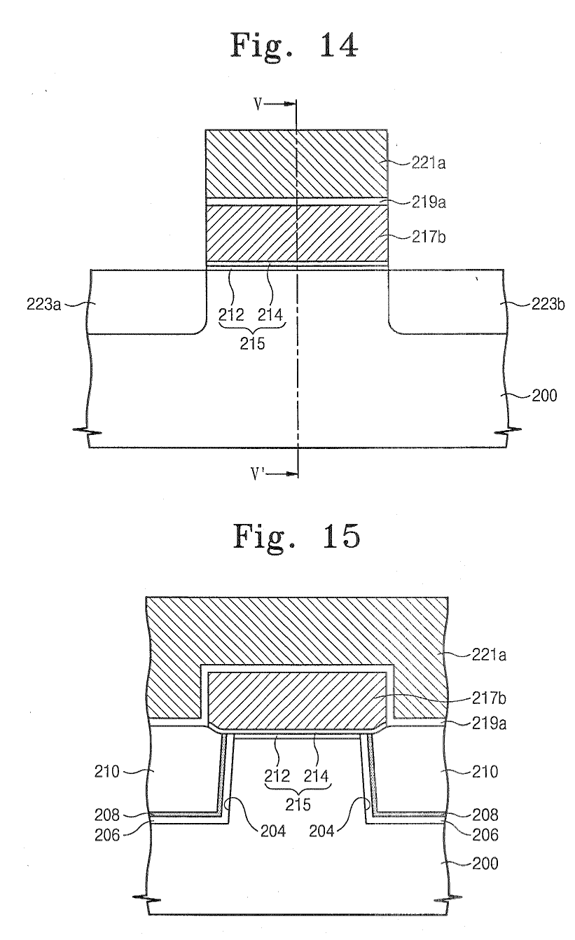

FIG. 14 is a sectional view illustrating a nonvolatile memory device in accordance with a third exemplary embodiment of the invention, and FIG. 15 is a sectional view taken along line V-V′ of FIG. 14.

Referring to FIGS. 14 and 15, trenches 204 are placed in a semiconductor substrate 200, defining active fields. Sidewall oxide films 206 are formed on sidewalls and bottoms of the trenches 204. The sidewall oxide films 206 are preferred to be made of, for example, thermal oxide. Thus, the sidewall oxide films 206 cure etching damages on the sidewalls and bottoms of the trenches 204. Liners 208 are formed covering the sidewall oxide films 206 formed on the bottoms and sidewalls of the trenches 204. Field isolation films 210a are disposed on the liners 208, filling the trenches 204. For example, the liners 208 may be made of nitride capable of buffing physical stress from the field isolation films 210 and the field isolation films 210 may be made of oxide.

Over the active field is disposed a floating gate 217b. Edges of the floating gate 217b cover the tops of the liners 208 disposed between the field isolation films 210 and the sidewalls of the trenches 204. The edges of the floating gate 217b may laterally extend to overlap with edges of the field isolation films 210 adjacent to the active fields.

Between the floating gate 217b and the active field is interposed a tunnel insulation film 215. The tunnel insulation film 215 includes first and second insulation layers 212 and 214 which are stacked in sequence. The second insulation layer 214 laterally extends to be interposed between the floating gate 217b and the liners 208. The second insulation layer 214, which is placed between the floating gate 217b and the liners 208, functions as a charge diffusion barrier.

This charge diffusion barrier is made of an insulative material capable of preventing charges from diffusion. For instance, the charge diffusion barrier is preferred to be formed of oxide. The charge diffusion barrier prevents charges from penetrating into the liners 208 out of the floating gate 217b.

For example, it is preferred for the first and second insulation layers 212 and 214 to be formed, respectively, of thermal oxide and oxide that is deposited by means of CVD or ALD. Accordingly, as the first insulation film 212 of thermal oxide constitutes a portion contacting with the active field, the interface characteristics between the tunnel insulation film 215 and the active field are thereby enhanced. Further, as the second insulation layer 214 is used in forming the top of the tunnel insulation film 215 and the charge diffusion barrier, charges are prevented from diffusing into the liners 208 out of the floating gate 217b.

A control gate electrode 221a capacitively coupled to the floating gate 217b crosses over the active field. The control gate electrode 221a entirely covers the floating gate 217b. The floating gate 217b is comprised of a couple of first sidewalls adjacent to the active field, and a couple of second sidewalls adjacent to the field isolation film 210. In this structure, the control gate electrode 221a has both sidewalls aligned to the couple of the first sidewalls. The control gate electrode 221a is preferred, for example, to cover the second sidewalls of the floating gate 217b. The floating gate 217b is interposed between the control gate electrode 221a and the active field. Between the control gate electrode 221a and the floating gate 217b is interposed an interlevel gate dielectric pattern 219a.

The floating gate 217b may be made of, for example, doped polysilicon. The interlevel gate dielectric pattern 219a may be formed of, for example, an oxide-nitride-oxide (ONO) layer. Alternatively, the interlevel gate dielectric pattern 219a may contain a high-dielectric film (e.g., metallic insulation oxide such as hafnium oxide or aluminum oxide) superior to the tunnel insulation film 215 in dielectric constant. The control gate electrode 221a may be formed of one material selected from, for example, doped polysilicon, metal (e.g., tungsten or molybdenum), conductive metal nitride (e.g., titanium nitride or tantalum nitride), and metal silicide (tungsten silicide or cobalt silicide).

A first impurity region 223a is disposed in the active field at a side of the control gate electrode 221a, while a second impurity region 223b is disposed in the active field at the other side of the control gate electrode 221b. The first and second impurity regions 223a and 223b are opposite to each other. Namely, the floating gate 217b and the control gate electrode 221a are sequentially stacked over the active field between the first and second impurity regions 223a and 223b.

According to the nonvolatile memory device of the present exemplary embodiment with the aforementioned structure, the charge diffusion barrier is interposed between the floating gate 217b and the liners 208, thereby preventing charges from diffusing into the liners 208 out of the floating gate 217b, and interrupting leakage current through a channel region adjacent to the liners. Further, the tunnel insulation film 215 is composed of the first and second insulation layers 212 and 214 and the first insulation layer 211 is formed of thermal oxide, thereby enhancing interface characteristics between the tunnel insulation film 215 and the active field to prevent degradation of the reliability of the nonvolatile memory device.

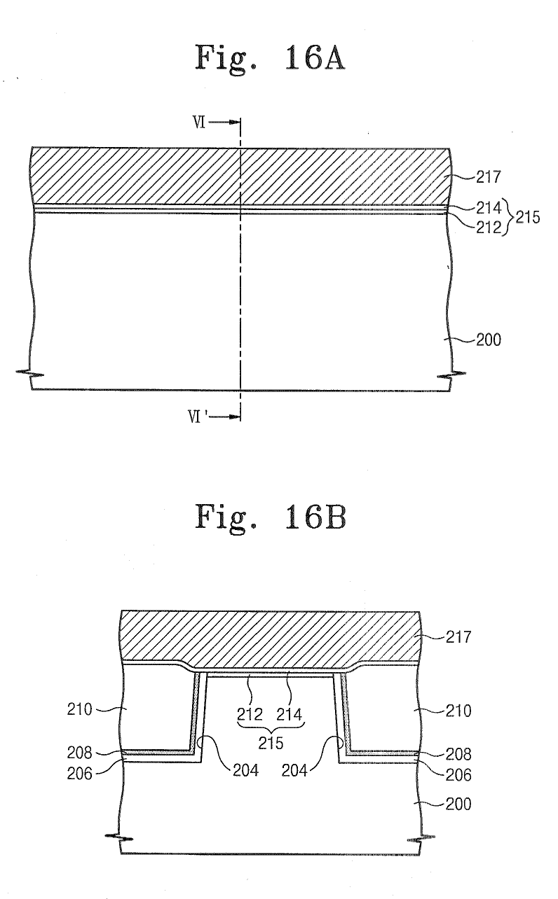

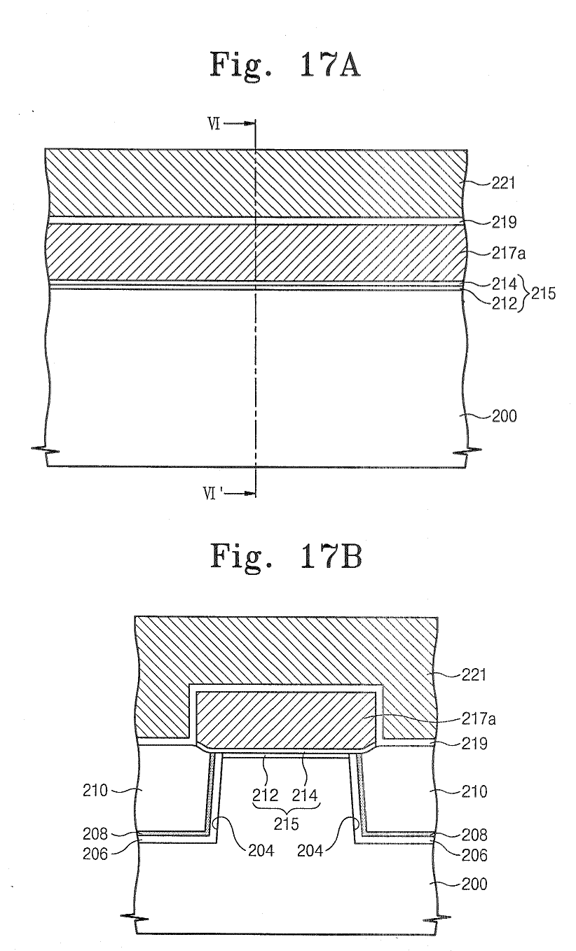

FIGS. 16A and 17A are sectional views illustrating a procedure of fabricating the nonvolatile memory device shown in FIG. 14, and FIGS. 16B and 17B are sectional views taken along line VI-VI′ of FIGS. 16A and 17A.

First, referring to FIGS. 16A and 17B, after forming the trenches 204 in predetermined regions of the substrate 200 for defining the active fields, the sidewall oxide films 206 are formed on the sidewalls and bottoms of the trenches 204. Then, after forming the liners 208 covering the sidewall oxide films 206 formed on the sidewalls and bottoms of the trenches 204, the field isolation films 210 are formed on the liners 208 to fill the trenches 204.

The forming of the trenches 204, the sidewall oxide films 206, the liners 208, and the field isolation films 210 may be carried out in the same manner as in the first exemplary embodiment. Namely, after forming a hard mask pattern on the substrate 200, using the hard mask pattern for a mask, the substrate 200 is selectively etched to form trenches 204. In addition, the sidewall oxide films 206 are deposited on the sidewalls and bottoms of the trenches 204 by means of thermal oxidation. After sequentially depositing a liner film and an insulation film, which fills the trenches 204, all over the substrate 200, the insulation film is flattened to form the field isolation films 210. By removing the hard mask pattern and the liner film from the tops and sidewalls of the hard mask pattern, the liners 208 are formed to expose the active fields.

Then, the substrate 200 including the disclosed active fields is thermally oxidized to form the first insulation layer 212. As the first insulation layer 212 is made of thermal oxide, it is able to be formed on the exposed surface of the active field and it provides improved interface characteristics between the first insulation layer 212 and the active field.

Thereafter, the second insulation layer 214 is deposited all over the substrate 200 including the first insulation layer 212. For example, the second insulation layer 214 is preferred to be made of oxide by means of CVD or ALD. The second insulation layer 214 is also preferred to be formed of, for example, an insulative material, e.g., oxide, capable of blocking charge diffusion. The second insulation layer 214 covers the field isolation films 210 and the tops of the liners 208, as well as the first insulation layer 212. The first and second insulation layer 214 covering the tops of the liners 208 is correspondent with the charge diffusion barrier.

After forming the second insulation layer 214, thermal treatment is carried out to enhance the interface characteristics between the first and second insulation layers 212 and 214.

Then, the floating gate film 217 is deposited all over the substrate 200 including the tunnel insulation film 215 and the charge diffusion barrier. The floating gate film 217 may be formed of, for example, doped polysilicon.

Subsequently, referring to FIGS. 17A and 17B, the floating gate film 217 is patterned to form a preliminary floating gate 217a. The preliminary gate 217a is able to entirely cover to the active field. The preliminary floating gate 217a covers the tops of the liners 208. The preliminary floating gate 217a may also cover the edges of the field isolation films 210.

Thereafter, the interlevel gate dielectric film 219 is formed on the substrate 200 including the preliminary floating gate 217a. Moreover, the control gate conductive film 221 is deposited on the interlevel gate dielectric film 219.

The control gate conductive film 221, the interlevel gate dielectric film 219, and the preliminary floating gate 217a are sequentially patterned to the floating gate 217b, the interlevel gate dielectric pattern 219a, and the control gate electrode 221a, stacked in sequence, as shown in FIGS. 14 and 15.

Next, using a mask with the control gate electrode 221a, ionic impurities are implanted into the substrate 200 to form the first and second impurity regions 223a and 223b shown in FIG. 14, thereby resulting in the nonvolatile memory device shown in FIGS. 14 and 15.

### FOURTH EXEMPLARY EMBODIMENT

This exemplary embodiment shows a nonvolatile memory device equipped with another type of charge diffusion barrier, being modified from the nonvolatile memory device of the third exemplary embodiment. The nonvolatile memory device according to this exemplary embodiment is similar to that of the third exemplary embodiment. The elements of this exemplary embodiment which are the same as elements of the third exemplary embodiment will be referred to in the present exemplary embodiment using the same reference numerals as used in the third exemplary embodiment.

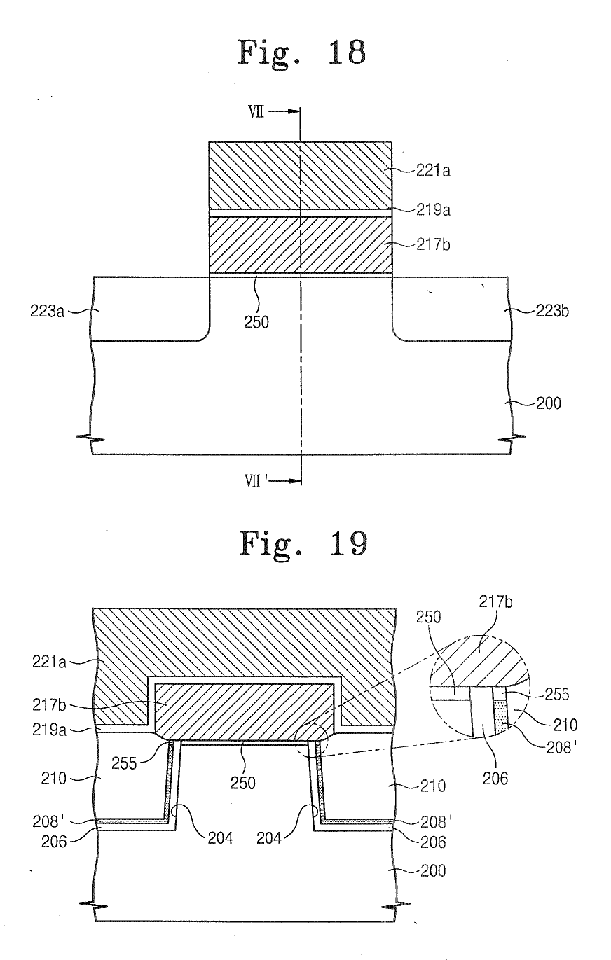

FIG. 18 is a sectional view illustrating a nonvolatile memory device in accordance with a fourth exemplary embodiment of the invention, and FIG. 19 is a sectional view taken along line VII-VII′ of FIG. 18.

Referring to FIGS. 18 and 19, the trenches 204 are formed in the substrate 200, defining the active fields therein. The sidewall oxide films 206 are formed on the sidewalls and bottoms of the trenches 204. Liners 208′ cover the sidewall oxide films 206 on the sidewalls and bottoms of the trenches 204. The field isolation films 210 are disposed on the liners 208′, thereby filling the trenches 204.

The charge diffusion barriers 255 are interposed between the field isolation films 210 and the upper portions of the sidewalls of the trenches 204. In further detail, the charge diffusion barriers 255 may be interposed between the field isolation films 210 and the upper portions of the sidewall oxide films 206 formed on the sidewalls of the trenches 204. The charge diffusion barriers 255 are stacked each on the tops of the liners 208′ interposed between the field isolation films and the sidewalls of the trenches 204. The tops of the liners 208′, which contact the charge diffusion barriers 255, are preferred to be leveled lower than the tops of the sidewall oxide films 206 formed on the sidewalls of the trenches 204.

The floating gate 217b is disposed over the active field. The edges of the floating gate 217b cover the charge diffusion barriers 255. In other words, the charge diffusion barriers 255 are interposed between the edges of the floating gate 217b and the tops of the liners 208′. The edges of the floating gate 217b may further cover the edges of the field isolation films 210 adjacent to the active field.

The charge diffusion barriers 255 are made of an insulation material to prevent charges from diffusing out of the floating gates 217b. For instance, the charge diffusion barriers 255 are preferred to be formed of oxide. For example, it is preferred for the charge diffusion barriers 255 to be made of, for example, a radical oxide film. In further detail, the charge diffusion barriers 255 are preferred, for example, to be composed of such radical oxide films that are generated from oxidizing the tops of the liners 208′ shown in FIG. 15. As aforementioned, the radical oxide film means an oxide film oxidized with radical oxygen.

The charge diffusion barriers 255 contribute to preventing charges from penetrating into the liners 208′ out of the floating gate 217b, thereby blocking leakage current, and lessening degradation of the reliability of the nonvolatile memory device.

A tunnel insulation film 250 is placed between the floating gate 217b and the active field. The tunnel insulation film 250 is preferred to contain, for example, one of radical oxide and thermal oxide.

The control gate electrode 221a crosses over the active field. The floating gate 217b is interposed between the control gate electrode 221a and the active field. Between the control gate electrode 221a and the floating gate 217b is placed the interlevel gate dielectric pattern 219a. The control gate electrode 221a and the interlevel gate dielectric pattern 219a have been already described in the mode of the third exemplary embodiment, and thus will not be further explained.

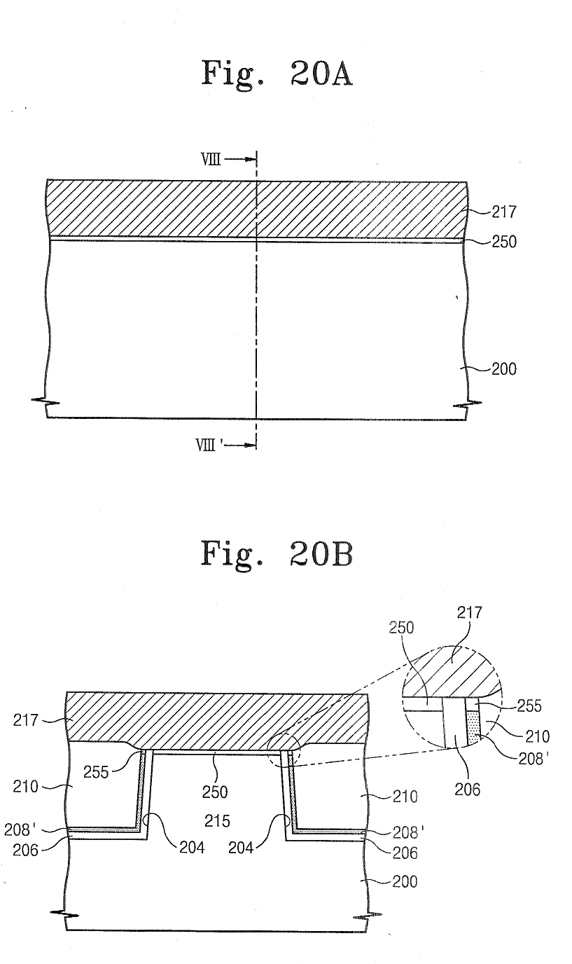

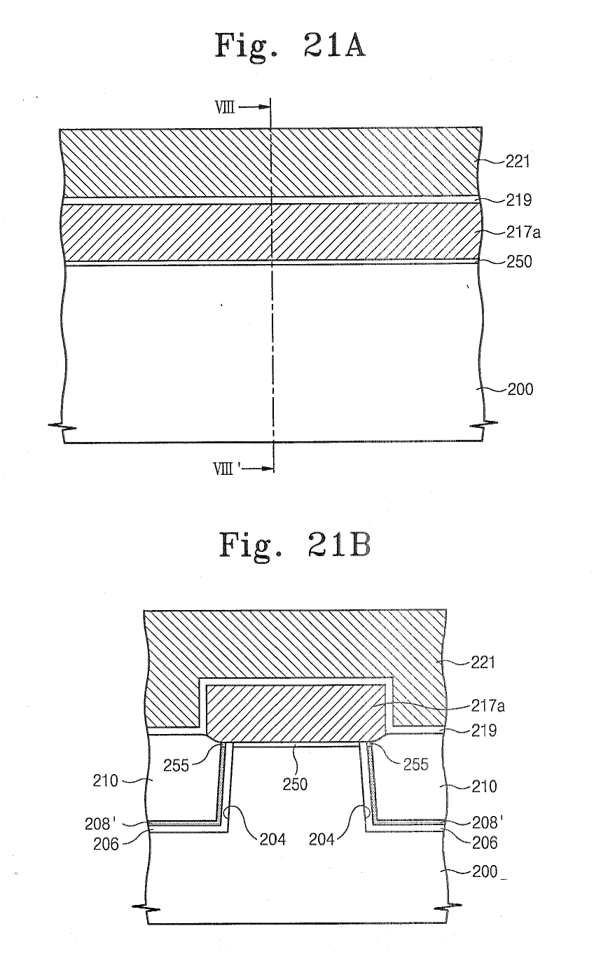

FIGS. 20A and 21A are sectional views illustrating a procedure of fabricating the nonvolatile memory device shown in FIG. 18, and FIGS. 20B and 21B are sectional views taken along line VIII-VIII′ of FIGS. 20A and 21B.

First, referring to FIGS. 20A and 20B, the trenches 204 confining the active fields in predetermined areas of the substrate 200, the sidewall oxide films 206 on the sidewalls and bottoms of the trenches 204, the liners 208′ covering the sidewall oxide films 206, and the field isolation films 210 filling the trenches 204 on the liners 208′ are sequentially formed. The forming of the trenches 204, the sidewall oxide films 206, the liners 208′, and the field isolation films 210 may be carried out in the same manner as in the third exemplary embodiment.

Then, an operation of oxidation with radical oxygen is carried out on the substrate 200 where the tops of the liners 208′ interposed between the sidewall oxide films 206 and the field isolation films 210 are exposed. This operation of radical oxidation is same as that of the second exemplary embodiment.

Thereby, the tops of the liners 208′ are radically oxidized to generate the charge diffusion barriers 255 by highly reactive radical oxygen. The tops of the liners 208′ under the charge diffusion barriers 255, which are not oxidized, may be leveled lower than the tops of the sidewall oxide films 206 formed on the sidewalls of the trenches 204.

Next, the tunnel insulation film 250 is deposited on the active field. The tunnel insulation film 250 may be formed of radical oxide made by way of the radical oxidation process that oxidizes the active field. Namely, the radical oxidation may be carried out to form the tunnel insulation film 250 on the active field, and the charge diffusion barriers 255 on the liners 208′, at a time.

Alternatively, the tunnel insulation film 250 may be formed by means of thermal oxidation before beginning the radical oxidation. In further detail, the tunnel insulation film 250 can be made of, for example, thermal oxide. In this case, the radical oxidation is conducted after completing the thermal oxidation. Therefore, the tunnel insulation film 250 may be constructed in the structure with a thin radical oxide film on a thermal oxide film. Namely, the tunnel insulation film 250 may be comprised of, for example, the thermal and radical oxide films.

Thereafter, the floating gate film 217 is formed on the substrate 200 including the tunnel insulation film 250 and the charge diffusion barriers 255. The floating gate film 217 may be made of, for example, doped polysilicon.

Next, referring to FIGS. 21A and 21B, the floating gate film 217 is patterned to form the preliminary floating gate 217a. The preliminary floating gate 217a may cover the active field entirely. The charge diffusion barriers 255 are covered by the edges of the preliminary floating gate 217a adjacent to the field isolation films 210. In addition, the edges of the preliminary floating gate 217a may cover the edges of the field isolation films 210 adjacent to the active field.

Then, the interlevel gate dielectric film 219 is deposited all over the substrate 200 and the control gate conductive film 221 is deposited on the interlevel gate dielectric film 219. The control gate conductive film 221, the interlevel gate dielectric film 219, and the preliminary floating gate 217a are sequentially patterned to form the control gate electrode 221a, the interlevel gate dielectric pattern 219a, and the control gate electrode 221a, respectively, as shown in FIGS. 18 and 19.

Using a mask with the control gate electrode 221a, ionic impurities are injected into the active fields to form the first and second impurity regions 223aand 223b shown in FIG. 18, thereby producing the nonvolatile memory device shown in FIGS. 18 and 19.

As described above, according to exemplary embodiments of the invention, the charge diffusion barriers which are interposed between the floating gate and the liners, are beneficial in preventing charges from diffusing into the liners out of the floating gate. Hence, with the exemplary embodiments of the present invention, a leakage current flowing through channel regions adjacent to the liners may be interrupted, thereby preventing degradation of the reliability of the nonvolatile memory device.

Moreover, with exemplary embodiments of the present invention, the tunnel insulation film contacts the active field through, for example, a thermal or radical oxide film, which contributes to maintain improved interface characteristics between the tunnel oxide film and the active field. As a result, the degradation of the interface characteristics between the tunnel oxide film and the active field in the nonvolatile memory device may be presented.

Having described the exemplary embodiments of the present invention, it is further noted that it is readily apparent to those of reasonable skill in the art that various modifications may be made without departing from the spirit and scope of the invention which is defined by the metes and bounds of the appended claims.

What is claimed is:

1. A nonvolatile memory device comprising:
a liner covering a sidewall and bottom of a trench that defines an active field in a substrate;
a field isolation film disposed on the liner which fills the trench;
a floating gate disposed on the active field, the floating gate having edge of which covers the liner;
a tunnel insulation film interposed between the active field and the floating gate; and
a charge diffusion barrier interposed between the liner and the floating gate.

2. The nonvolatile memory device as set forth in claim 1, wherein the tunnel insulation film comprises first and second insulation layers,
wherein the second insulation layer extends laterally to be interposed between the floating gate and the liner,
wherein the second insulation layer interposed between the floating gate and the liner is the charge diffusion barrier.

3. The nonvolatile memory device as set forth in claim 2, wherein the first insulation layer is a thermal oxide film while the second insulation film is an oxide film formed by means of chemical vapor deposition or atomic layer deposition.

4. The nonvolatile memory device as set forth in claim 1, wherein the charge diffusion barrier is interposed between the field isolation and an upper portion of the sidewall of the trench and stacked on the liner interposed between the field isolation film and the sidewall of the trench.

5. The nonvolatile memory device as set forth in claim 1, wherein the charge diffusion barrier is an oxide film oxidized by radical oxygen.

6. The nonvolatile memory device as set forth in claim 1, which further comprises a control gate electrode crossing over the active field and being coupled to the floating gate.

7. The nonvolatile memory device as set forth in claim 6, which further comprises:
a capping oxide pattern disposed on the floating gate and having an elliptical section; and
a control gate insulation film interposed at least between the control gate electrode and a sidewall of the floating gate and between the active field and the control gate electrode,
wherein the control gate electrode covers the sidewall and partially a top of the floating gate, and a part of the active field adjacent to the sidewall of the floating gate,
wherein a top edge of the floating gate is shaped in a sharpened tip and the capping oxide pattern is partially disposed between the floating gate and the control gate electrode.

8. The nonvolatile memory device as set forth in claim 6, which further comprises an interlevel gate dielectric pattern interposed between the floating gate and the control gate electrode,
wherein the control gate electrode covers the floating gate entirely and has a couple of sidewalls aligned to both sidewalls of the floating gate,

9. The nonvolatile memory device as set forth in claim 6, which further comprises a sidewall oxide film interposed between the liner and the sidewall of the trench and between the liner and a bottom of the trench.

10. A method for fabricating a nonvolatile memory device, comprising:
forming a trench to define an active field in a substrate;
forming a liner to cover a sidewall and bottom of the trench; forming a field isolation film on the liner to fill the trench;
forming a tunnel insulation film on the active field;
forming a floating gate, over the active field, wherein the floating gate has an edge which covers the liner; and
forming a charge diffusion barrier interposed between the liner and the floating gate.

11. The method as set forth in claim 10, wherein the forming of the tunnel insulation film and the charge diffusion barrier comprises:
thermally oxidizing the substrate to form a thermal oxide film on the surface of the active field; and
depositing an oxide film on the substrate by means of one of chemical vapor deposition or atomic layer deposition,
wherein the floating gate is formed on the deposited oxide film, the thermal and deposited oxide films interposed between the floating gate and the active field are correspondent with the tunnel insulation film, and the deposited oxide film interposed between the floating gate and the liner is the charge diffusion barrier.

12. The method as set forth in claim 10, wherein the forming of the charge diffusion barrier is comprised of conducting radical oxidation on the substrate with radical oxygen and oxidizing the top of the liner,
wherein the oxidized top of the liner is the charge diffusion barrier.

13. The method as set forth in claim 12, wherein the tunnel insulation film is formed by oxidizing the surface of the active field by the radical oxidation.

14. The method as set forth in claim 12, wherein the forming of the tunnel insulation film is comprised of thermally oxidizing the surface of the active field before the radical oxidation.

15. The method as set forth in claim 10, which further comprises: forming a control gate electrode to cross over the active field and to be coupled to the floating gate.

16. The method as set forth in claim 15, wherein forming the floating gate and the control gate electrode comprises:
forming a floating gate film all over the substrate including the tunnel insulation film and the charge diffusion barrier;
forming a capping oxide pattern with an elliptical section on a portion of the floating gate film by oxidation;
patterning the floating gate film using the capping oxide pattern as a mask to form the floating gate;
forming a control gate insulation film to cover at least both sidewalls of the floating gate and the active field at both sides of the floating gate; and
forming a control gate electrode to cover a part of the capping oxide pattern, one sidewall of the floating gate and a part of the active field adjacent to the one sidewall of the floating gate.

17. The method as set forth in claim 15, wherein the forming of the floating gate and the control gate electrode comprises:
forming a floating gate film all over the substrate including the tunnel insulation film and the charge diffusion barrier;
patterning the floating gate film to form a preliminary floating gate covering the active field and the charge diffusion barrier;
forming an interlevel gate dielectric film and a control gate conductive film in sequence all over the substrate; and
patterning the control gate conductive film, the interlevel gate dielectric film, and the preliminary floating gate to form the floating gate, an interlevel gate dielectric pattern, and the control gate electrode being stacked in sequence.

18. The method as set forth in claim 15, which is further comprises forming a sidewall oxide film on the sidewall and bottom of the trench before forming the liner,
wherein the sidewall oxide film includes thermal oxide.
